(19) United States
(12) Patent Application Publication
(10) Pub. No.: US 2015/0181753 A1
(43) Pub. Date: Jun. 25, 2015

(54) ELECTRONIC APPARATUS, RAIL STRUCTURE AND RACK

(71) Applicant: Fujitsu Limited, Kawasaki-shi (JP)

(72) Inventor: HAJIME MURAKAMI, Kawasaki (JP)

(21) Appl. No.: 14/485,892

(22) Filed: Sep. 15, 2014

(30) Foreign Application Priority Data
Dec. 20, 2013 (JP) 2013-264547

(51) Int. Cl. H05K 7/18; H05K 5/02

(52) U.S. Cl. CPC H05K 7/183; H05K 5/0221

(57) ABSTRACT

An electronic apparatus, comprising: a rack including a far side post, a near side post, and an opening formed at a side of the near side post; a pair of rail members to slidably move, the pair of rail members including: a first rail member attached to the far side post, and a second rail member attached to the near side post; an engaging member, provided at an end portion of the first rail member, to engage with an engaged portion formed on the far side post, to block movement of the engaging member in a disengaging direction; an unlocking member, provided on the second rail member, to move the locking member to an unlocking position of the engaging member by sliding the second rail member; and an electronic device mounted on the pair of rail members.

### CROSS-REFERENCE TO RELATED APPLICATION

This application is based upon and claims the benefit of priority from the prior Japanese Patent Application No. 2013-264547 filed on Dec. 20, 2013, the entire contents of which are incorporated herein by reference.

### FIELD

The technology disclosed herein relates to an electronic apparatus, a rail structure and a rack.

### BACKGROUND

In a related structure, an engaging piece is attached to a plate spring on a mount rail for mounting a communication device and is caught by a rear face side mount angle by biasing force of the plate spring. In another related structure, a disconnection mechanism for cancelling connection between a mount kit and a mount angle is provided in each of kit connection mechanisms at both end portions of the mount kit.

Related art is disclosed in Japanese Laid-open Patent Publication No. 2009-206129 and Japanese Laid-open Patent Publication No. 2010-62264.

### SUMMARY

According to one aspect of the embodiments, an electronic apparatus, comprising: a rack including a far side post, a near side post, and an opening formed at a side of the near side post; a pair of rail members configured to slidably move relative to each other, the pair of rail members including: a first rail member attached to the far side post, and a second rail member attached to the near side post; an engaging member, provided at an end portion of the first rail member, configured to engage with an engaged portion formed on the far side post in a state in which the pair of rail members are inserted through the opening of the rack;

a locking member, provided on the first rail member, configured to block a movement of the engaging member in a disengaging direction; an unlocking member, provided on the second rail member, configured to move the locking member to an unlocking position of the engaging member by a sliding operation of the second rail member; and an electronic device mounted on the pair of rail members.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of an electronic apparatus as viewed from the near side;

FIG. 2 is a top plan view of an installation room for an electronic apparatus;

FIG. 3 is a perspective view of a rack mount rail;

FIG. 4 is a sectional view taken along line F4-F4 of FIG. 3;

FIG. 5 is a perspective view of a rack mount rail at a first end portion side;

FIG. 6 is an exploded perspective view of a rack mount rail at a first end portion side;

FIG. 7A is a perspective view of a rack mount rail;

FIG. 7B is another perspective view of a rack mount rail;

FIG. 7C is a further perspective view of a rack mount rail;

FIG. 8 is a perspective view of a rack mount rail at a second end portion side;

FIG. 9 is a top plan view of a rack mount rail at a second end portion side;

FIG. 10A is a perspective view depicting a rack mount rail in a state in which the rack mount rail is attached to a rack;

FIG. 10B is a perspective view depicting a rack mount rail in another state in which the rack mount rail is attached to a rack;

FIG. 10C is a perspective view depicting a rack mount rail in a further state in which the rack mount rail is attached to a rack;

FIG. 11A is a sectional view of a rack mount rail at a first end portion side in a state in which the rack mount rail is attached to a rack;

FIG. 11B is a sectional view of a rack mount rail at a first end portion side in another state in which the rack mount rail is attached to a rack;

FIG. 11C is a sectional view of a rack mount rail at a first end portion side in a further state in which the rack mount rail is attached to a rack;

FIG. 11D is a sectional view of a rack mount rail at a first end portion side in a still further state in which a rack mount rail is attached to a rack;

FIG. 11E is a sectional view of a rack mount rail at a first end portion side in a yet further state in which a rack mount rail is attached to a rack;

FIG. 11F is a sectional view of a rack mount rail at a first end portion side in a yet further state in which the rack mount rail is attached to a rack;

FIG. 12A is a perspective view depicting a rack mount rail in a state in which the rack mount rail is removed from a rack;

FIG. 12B is a perspective view depicting a rack mount rail in another state in which the rack mount rail is removed from a rack;

FIG. 12C is a perspective view depicting a rack mount rail in a further state in which the rack mount rail is removed from a rack;

FIG. 13A is a sectional view of a rack mount rail at a first end portion side in a state in which the rack mount rail is removed from a rack;

FIG. 13B is a sectional view of a rack mount rail at a first end portion side in another state in which the rack mount rail is removed from a rack;

FIG. 13C is a sectional view of a rack mount rail at a first end portion side in a further state in which the rack mount rail is removed from a rack;

FIG. 13D is a sectional view of a rack mount rail at a first end portion side in a still further state in which the rack mount rail is removed from a rack;

FIG. 13E is a sectional view of a rack mount rail at a first end portion side in a yet further state in which the rack mount rail is removed from a rack; and

FIG. 13F is a sectional view of a rack mount rail at a first end portion side in a yet further state in which the rack mount rail is removed from a rack.

### DESCRIPTION OF EMBODIMENT

In such structures as described above, an operator would go around to the far side of the rack and perform attachment or removal of the rail member located at the far side of the rack.

In the following, an embodiment of the technology disclosed herein is described.

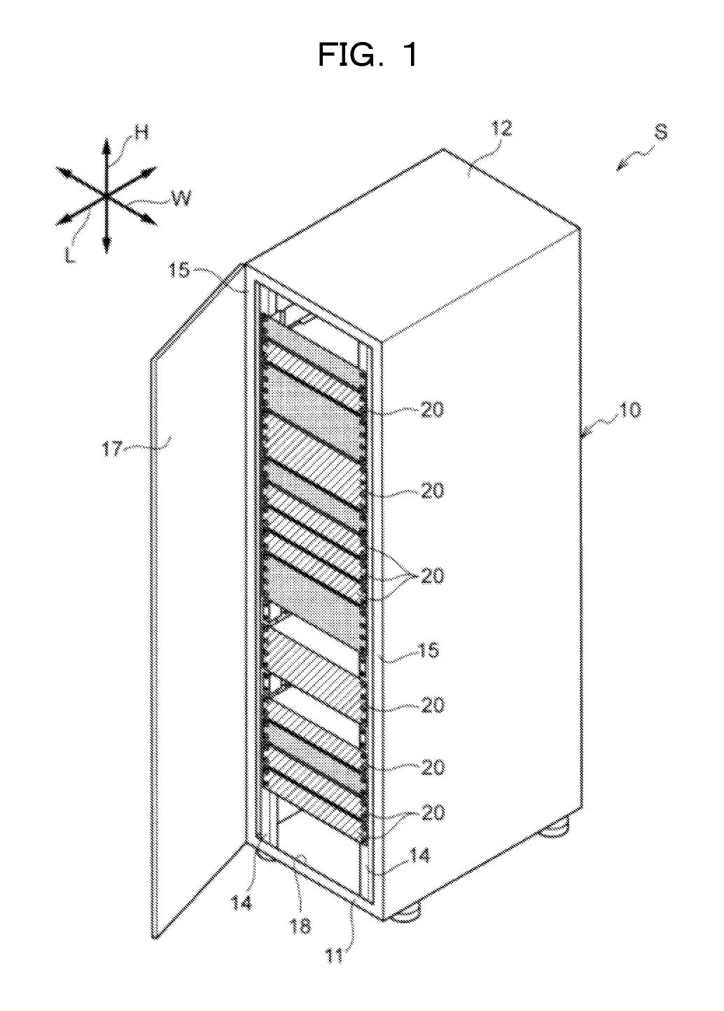

As depicted in FIG. 1, an electronic apparatus S according to the present embodiment includes a rack 10, and a plurality of electronic devices 20. In FIG. 1, an arrow mark L indicates a depthwise direction of the electronic apparatus S; another arrow mark W indicates a widthwise direction of the electronic apparatus S; and a further arrow mark H indicates a heightwise direction of the electronic apparatus S. A depthwise direction, a widthwise direction and a heightwise direction of each of the rack 10 and the electronic devices 20 are similar to above-described directions of the electronic apparatus S. A front side of the rack 10 corresponds to the “near side,” and a rear side of the rack 10 corresponds to the “far side.”

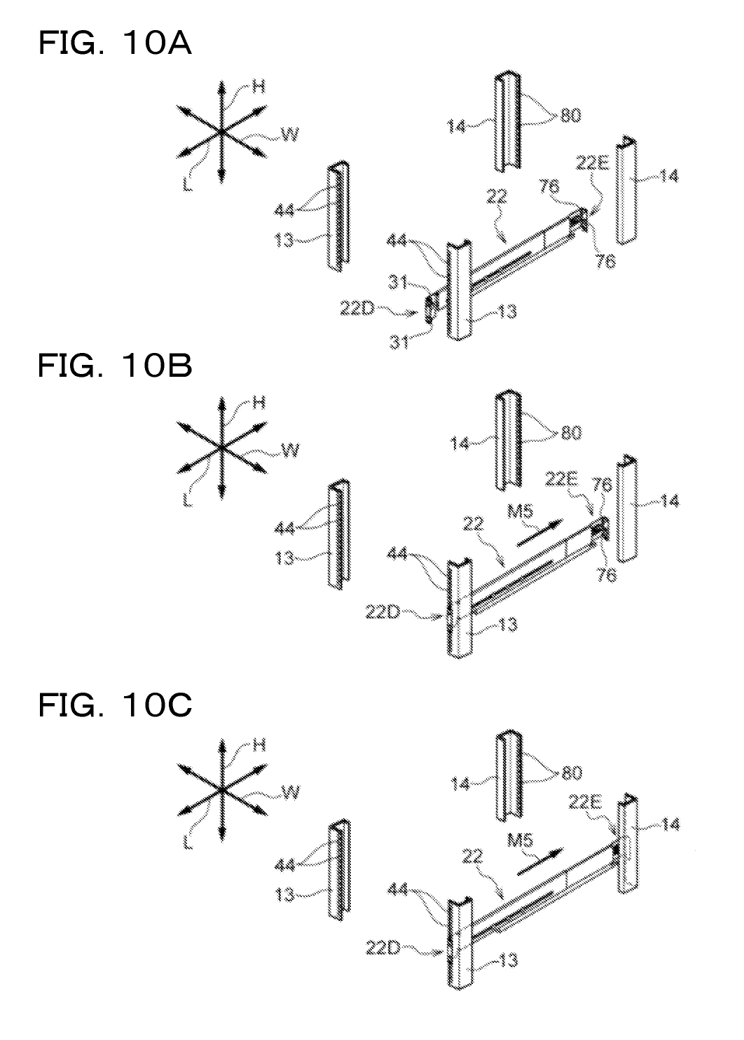

The rack 10 is formed in a rectangular parallelepiped elongated in a vertical direction. The rack 10 includes a lower frame 11, an upper plate 12, a pair of left and right far side posts 13 (refer to FIGS. 10A to 10C), a pair of left and right near side posts 14 (refer to FIGS. 10A to 10C), a pair of left and right vertical frames 15, and a front door 17. The front door 17 opens and closes an opening 18 of the rack 10 at the near side. The front door 17 is opened to open the opening 18, and a rack mount rail 22 is placed into or out of the rack 10 or an electronic device 20 is attached to or removed from the rack 10 through the opening 18.

The plurality of electronic devices 20 may be mounted in a spaced relationship from each other in the heightwise direction in the rack 10. A gap between different ones of the electronic devices 20 may be closed by a closing plate 24. By closing the gap between the adjacent ones of the plurality of electronic devices 20 with the closing plate 24, leakage of air in the rack 10 can be reduced.

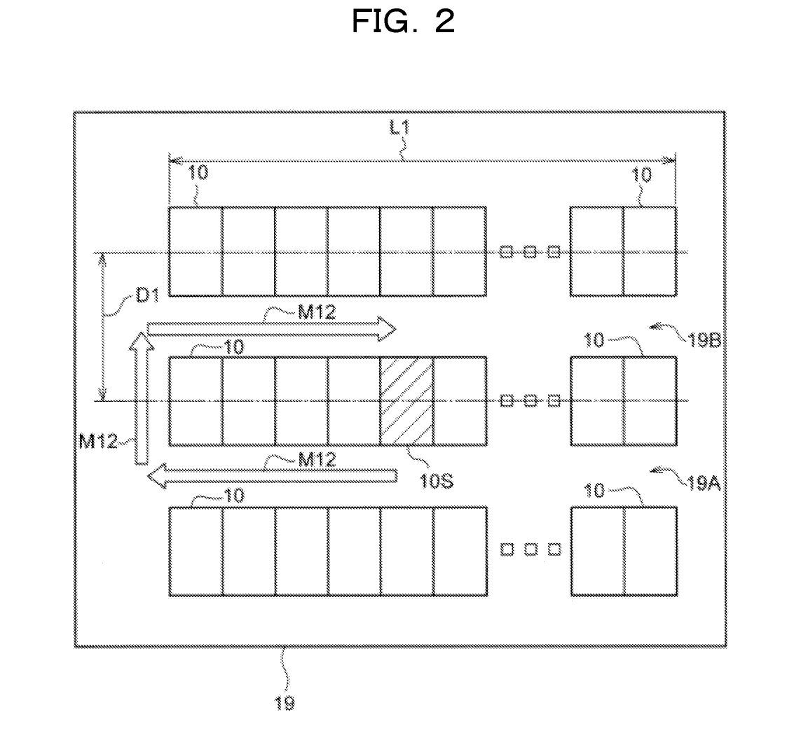

As depicted in FIG. 2, a plurality of racks 10 are located, for example, in an installation room 19 of a data center. In the installation room 19, the racks 10 are placed in lines as rack rows 10L such that a front face 10A of the racks 10 is positioned at a first passageway 19A side and a rear face 10B of the racks 10 is positioned at a second passageway 19B side. The rack rows 10L have a length L1 that may be, for example, 10 m or more. The rack rows 10L are spaced by a center-to-center distance D1 from each other. The center-to-center distance D1 may be, for example, approximately 2 m.

As depicted in FIG. 1, the plurality of electronic devices 20 may typically be servers. The electronic devices 20 are mounted in the rack 10 in a stacked state in the heightwise direction of the rack 10.

As depicted in FIGS. 10A to 10C, the rack mount rail 22 is bridged between a far side post 13 and a near side post 14 of the rack 10. The rack mount rail 22 is an example of one of a “pair of rail members” and an example of a “rail structure.”

It is to be noted that, while, in FIGS. 10A to 10C, the rack mount rail 22 is depicted only at the right side in FIGS. 10A to 10C in the widthwise direction, also at the left side in FIGS. 10A to 10C, another rack mount rail 22 is bridged between another far side post 13 and another near side post 14. In a state in which the rack mount rails 22 are bridged in one left and right set in the widthwise direction, an electronic device 20 is mounted on the one set of left and right rack mount rails 22.

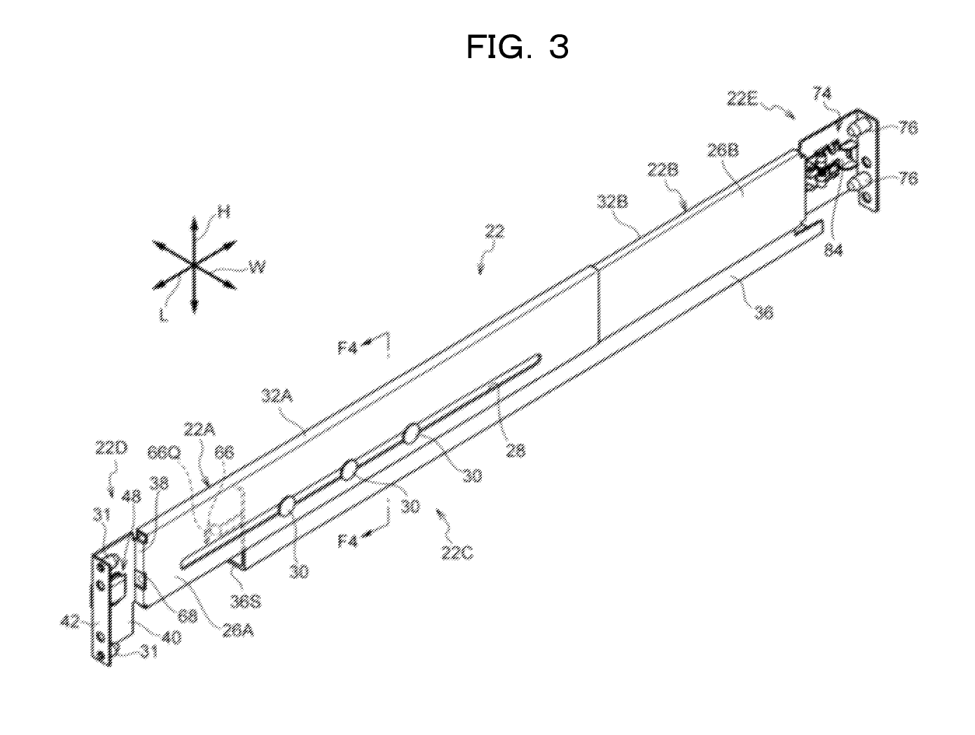

As depicted in FIG. 3, the rack mount rail 22 is structured such that a first fixing unit 22D and a second fixing unit 22E are coupled for movement toward and away from each other by a slide unit 22C. The first fixing unit 22D is fixed to the far side post 13. The second fixing unit 22E is fixed to the near side post 14.

As hereinafter described, the first fixing unit 22D includes engagement pins 31 and a locking member 48. The second fixing unit 22E includes engagement pins 76 and an attachment member 74.

The rack mount rail 22 includes a first rail member 22A and a second rail member 22B. The first rail member 22A is an example of a “first rail member,” and the second rail member 22B is an example of a “second rail member.”

The first rail member 22A includes a first plate portion 26A extending in the depthwise direction. The second rail member 22B includes a second plate portion 26B extending in the depthwise direction similarly. The first plate portion 26A has an elongated hole 28 formed along the depthwise direction. The second plate portion 28B has a plurality of pins 30 formed in a spaced relationship by a given distance from each other in the depthwise direction. The pins 30 are accommodated in the elongated hole 28. Consequently, the first rail member 22A and the second rail member 22B slidably move relative to each other in the longitudinal direction, and the rack mount rail 22 expands or contracts as a whole.

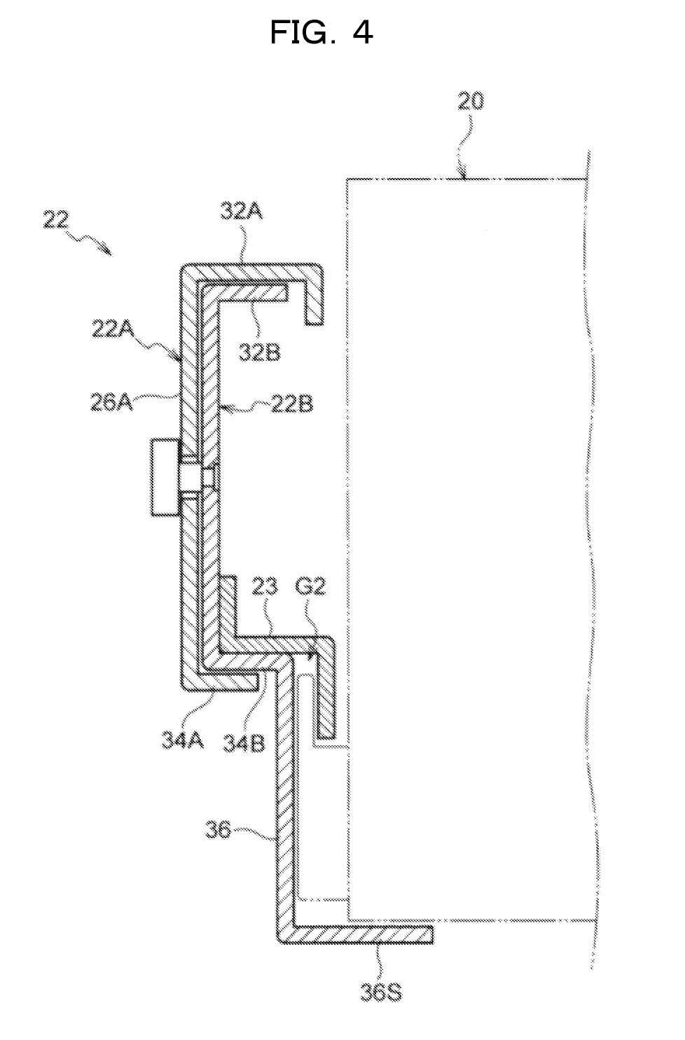

As depicted also in FIG. 4, an upper flange 32A and a lower flange 34A are formed at an upper end and a lower end of the first plate portion 26A, respectively. An upper flange 32B and a lower flange 34B are formed also at an upper end and a lower end of the second plate portion 28B, respectively. Since the upper flange 32B is positioned under the upper flange 32A and the lower flange 34B is positioned over the lower flange 34A, relative positional displacement of the second plate portion 26B and the first plate portion 26A in the vertical direction is reduced.

A holding plate 36 extends contiguously from a lower portion of the second plate portion 28B (lower flange 34B). The holding plate 36 is bent in a substantially L shape as viewed in the depthwise direction and includes a supporting portion 36S. The supporting portions 36S of the left and right rack mount rails 22 are opposed to each other and may support an electronic device 20.

The holding plate 23 is attached to the second rail member 22B. An electronic device 20 is partly accommodated in a gap G2 between the holding plate 36 and the holding plate 23 so that displacement of the electronic device 20 in the widthwise direction and the heightwise direction is restricted.

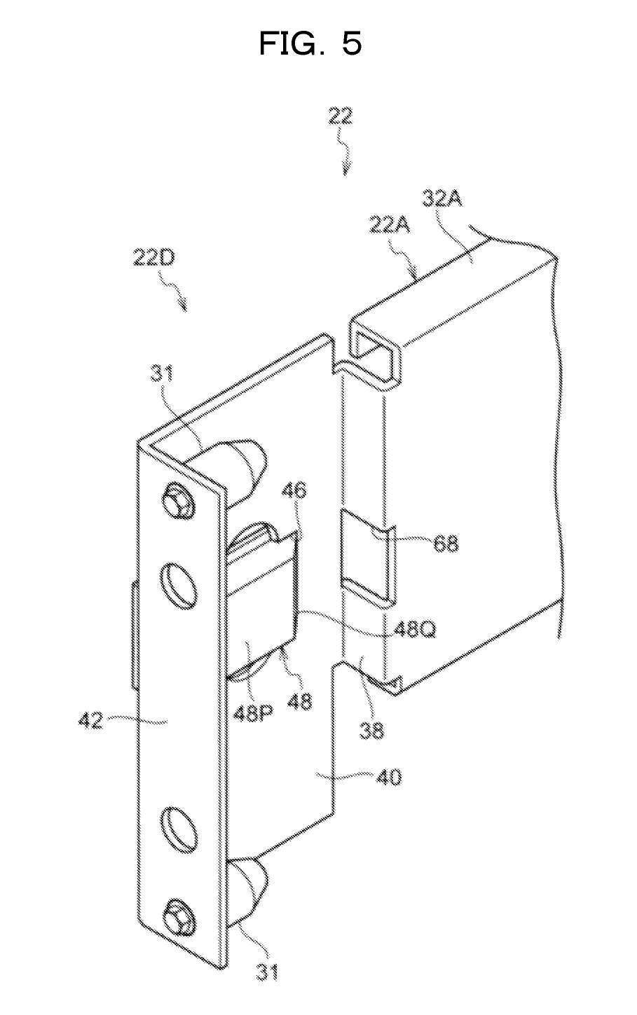

As depicted in FIGS. 3, 5 and 6, a stopper wall 38 having a normal direction coincident with the depthwise direction continues from a rear end of the first plate portion 26A. As depicted in FIGS. 7A to 7C, the second plate portion 26B slidably moves in the depthwise direction with respect to the first plate portion 26A. For example, as depicted in FIG. 7C, if the second rail member 22B slidably moves in a direction in which the rack mount rail 22 is shortened and the second plate portion 28B hits the stopper wall 38, the sliding movement is restricted. It is to be noted that the range of the sliding movement between the first rail member 22A and the second rail member 22B may be restricted, for example, by contact between end portions of the elongated hole 28 and the pins 30.

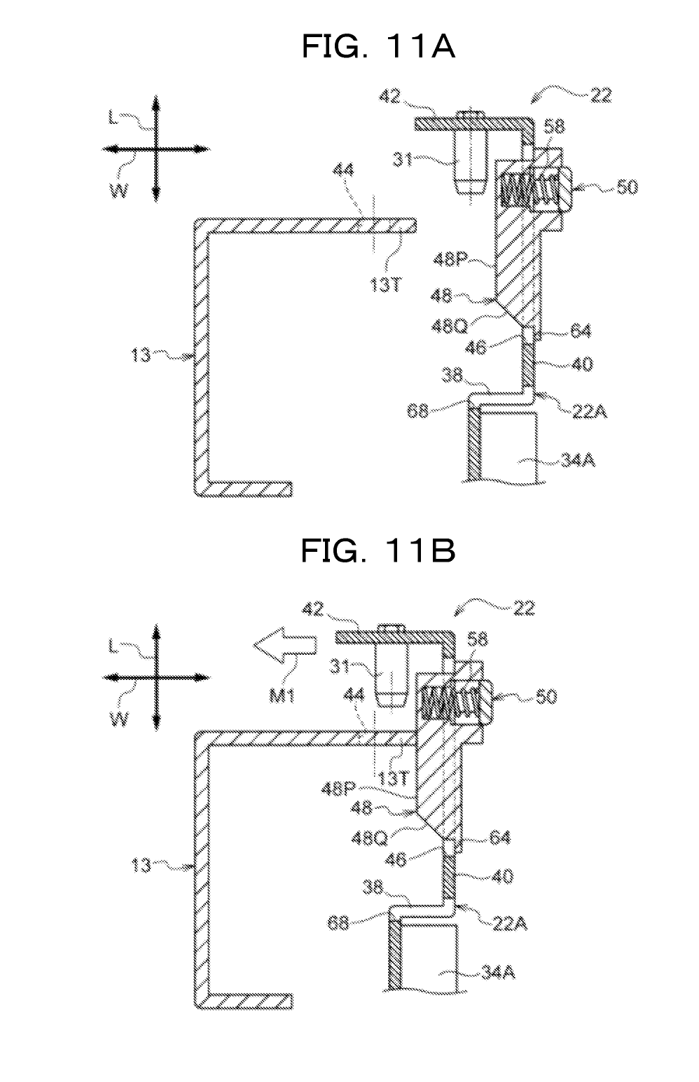

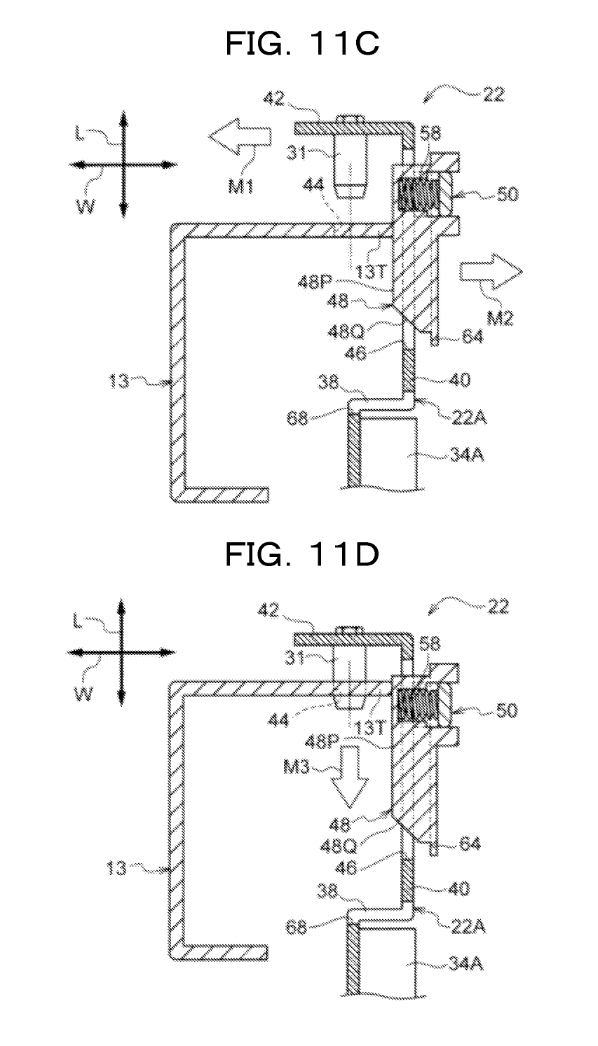

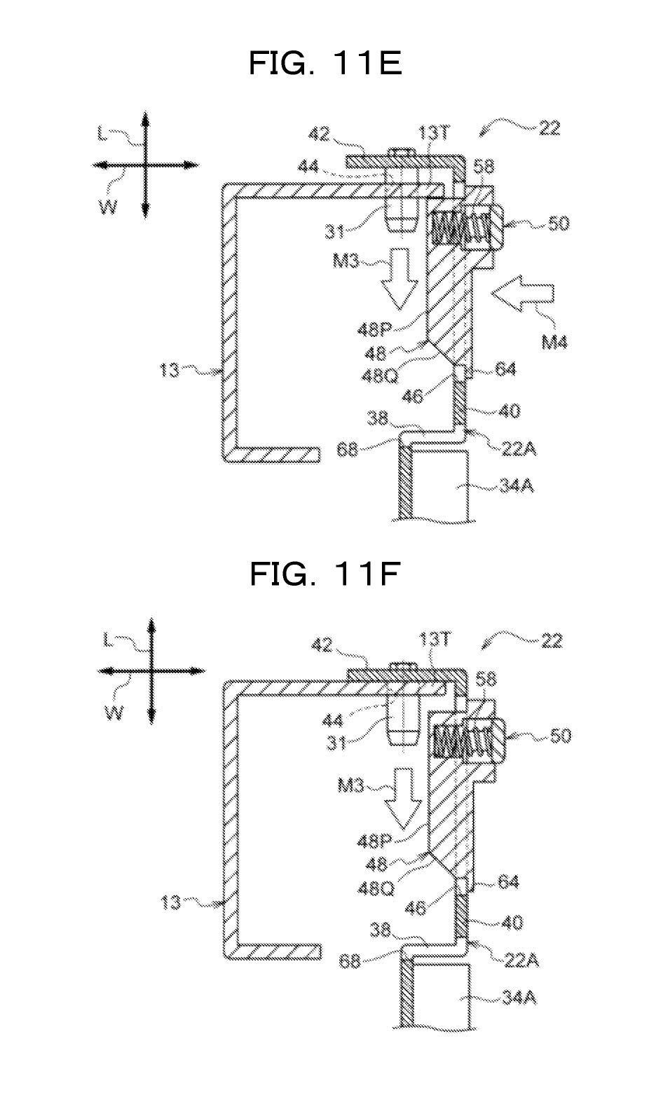

A connection plate 40 extends rearwardly from the stopper wall 38. A bent wall 42 having a normal line coincident with the depthwise direction is formed to extend from a rear end of the connection plate 40. One or a plurality of engagement pins 31 (in the example depicted in FIGS. 3, 5 and 6, two engagement pins 31 spaced from each other in the vertical direction) are provided in a forwardly projecting state on the bent wall 42. As depicted in FIGS. 11A to 11F, the engagement pin or pins 31 engage from the rear side with an engagement hole or holes 44 of the far side post 13.

A movement permitting hole 46 is formed in the middle of the connection plate 40. A locking member 48 is located in the movement permitting hole 46.

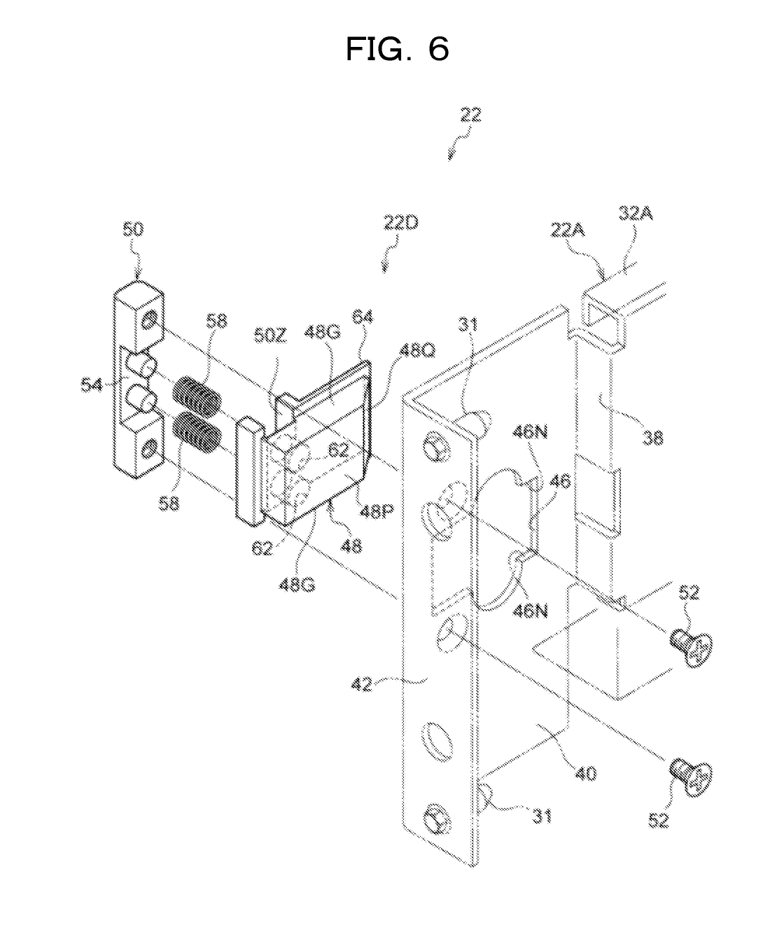

As depicted also in FIGS. 6 and 11A to 11F, the locking member 48 includes a flat face 48P parallel to the connection plate 40, and an inclined face 48Q inclined at a side nearer to the second rail member 22B than the flat face 48P.

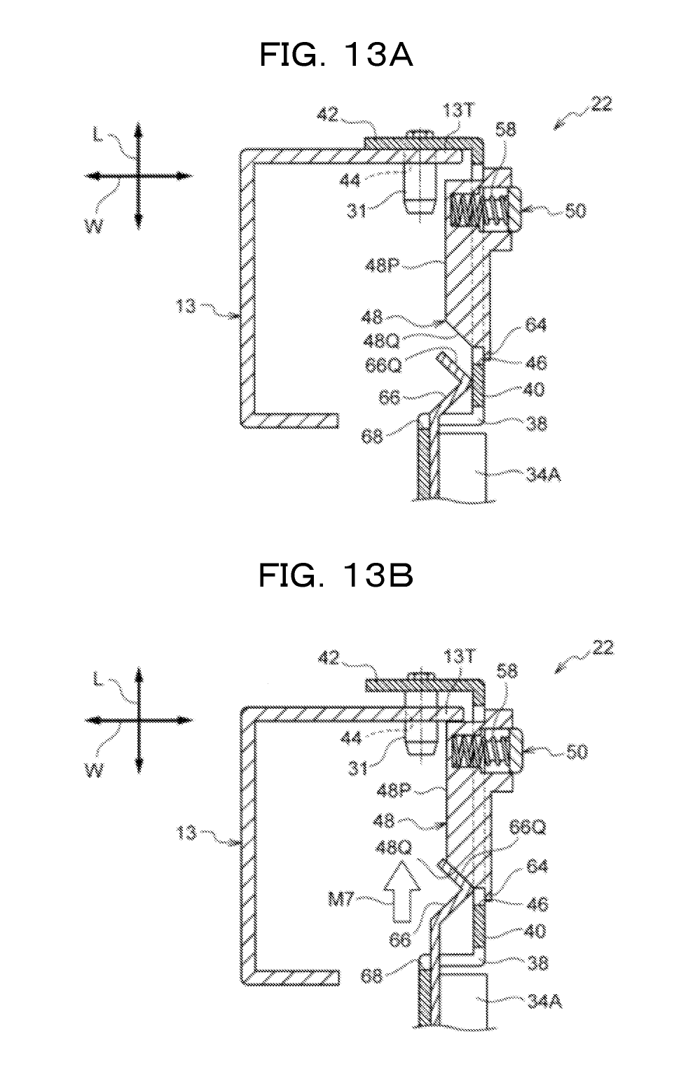

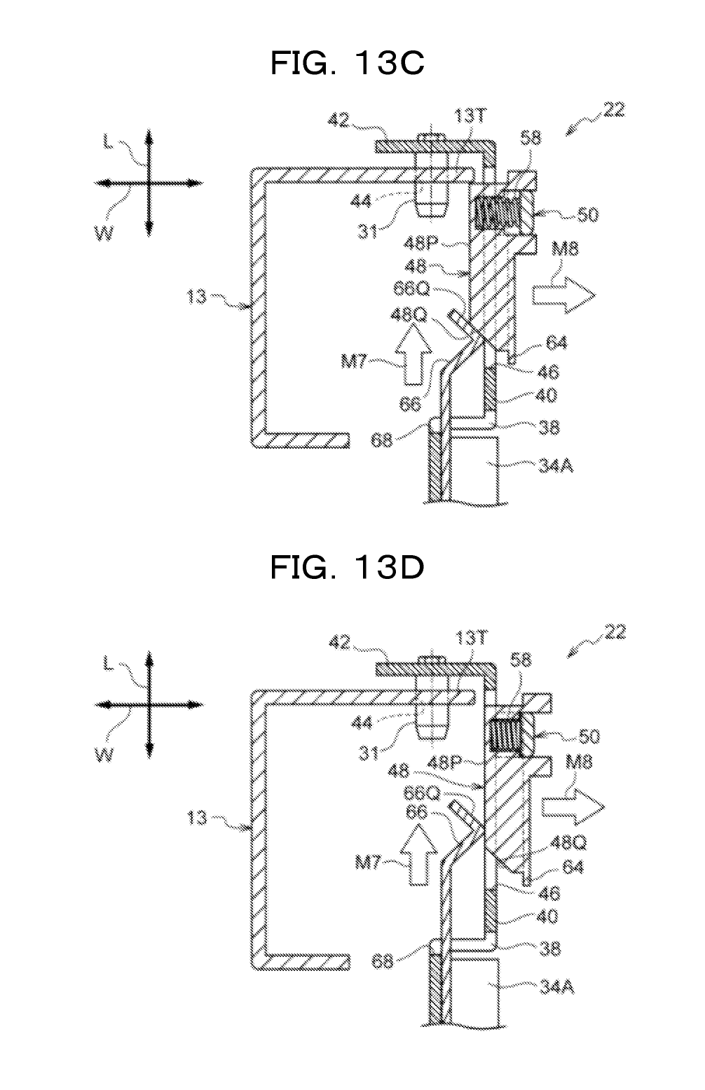

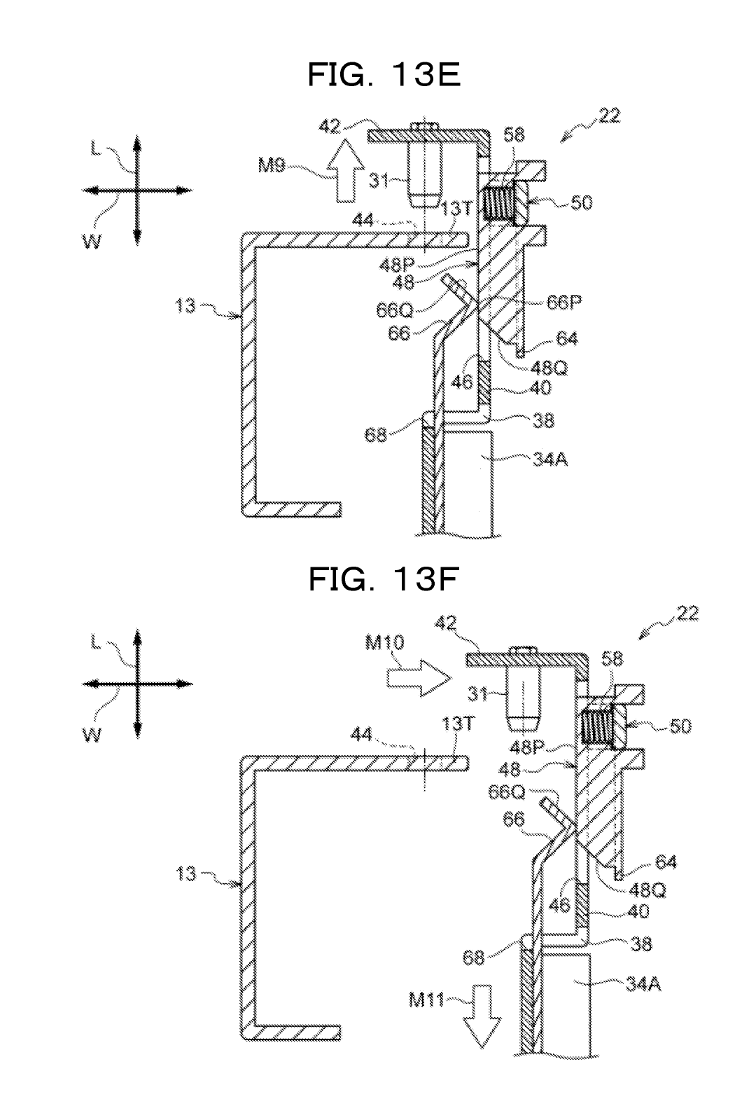

The locking member 48 is movable between a locking position (refer to FIG. 11F) at which the locking member 48 projects to the inner side in the widthwise direction from the movement permitting hole 46 and an unlocking position (refer to FIGS. 13D to 13F) at which the locking member 48 is retracted to the outer side in the widthwise direction. The direction of the movement of the locking member 48 is a direction (widthwise direction) orthogonal to the direction of the sliding movement between the first rail member 22A and the second rail member 22B.

As depicted in FIG. 6, a lock holding member 50 is fixed to the connection plate 40 by fixing screws 52 from the outer side in the widthwise direction. The lock holding member 50 restricts the movement of the locking member 48 to a fixed range.

A guide recessed portion 54 is formed on the locking member 48. A countersink portion 50Z of the lock holding member 50 is partly accommodated in the guide recessed portion 54. Gaps between upper and lower faces 48G of the locking member 48 and an inner face 46N of the movement permitting hole 46 are set small in the vertical direction. Consequently, a play of the locking member 48 with respect to the lock holding member 50 is reduced, and the direction of movement of the locking member 48 is guided to the widthwise direction.

One or a plurality of spring members 58 (in the example depicted in FIG. 6, two spring members 58 spaced from each other in the vertical direction) are located between the lock holding member 50 and the locking member 48. The spring members 58 are mounted on support pins 60 of the lock holding member 50 and accommodated in accommodating recesses 62 of the locking member 48, and consequently, positional displacement or dropping of the spring members 58 is reduced. The spring members 58 bias the locking member 48 toward the locking position.

A skirt portion 64 is formed around the locking member 48. When the locking member 48 is at the locking position, the skirt portion 64 contacts with the connection plate 40 around the movement permitting hole 46 to restrict movement of the locking member 48 to the inner side in the widthwise direction.

The locking position of the locking member 48 is a position at which, in a state in which the engagement pins 31 engage with the engagement holes 44, the locking member 48 extends toward the engagement pins 31 until the locking member 48 is positioned on the front side with respect to a tip end portion 13T of the far side post 13, as depicted in FIG. 11F. At this time, the bent wall 42 and the locking member 48 are opposed to each other such that the tip end portion 13T of the far side post 13 is placed between the bent wall 42 and the locking member 48.

On the other hand, the unlocking position of the locking member 48 is a position at which the locking member 48 is spaced away from the engagement pins 31 and retracted also from the tip end portion 13T of the far side post 13, as depicted in FIG. 13D. Since the locking member 48 is not positioned at the front side with respect to the far side post 13, it is possible to move the first rail member 22A to the rear side to remove the engagement pins 31 to the rear side from the engagement holes 44.

As depicted in FIGS. 3 and 13A to 13F, an unlocking projection 66 is provided at and extends from a rear end of the second rail member 22B toward the rear side. If the second rail member 22B slidably moves to the rear side with respect to the first rail member 22A, then the unlocking projection 66 projects to the rear side through a through-hole 68 formed in the stopper wall 38 of the first rail member 22A.

An inclined face 66Q is formed at a rear end side of the unlocking projection 66 so as to be inclined with respect to the depthwise direction. The inclined face 48Q of the locking member 48 is opposed in the depthwise direction to the inclined face 66Q when the locking member 48 is at the locking position.

As depicted in FIG. 13B, if the unlocking projection 66 moves to the rear side when the locking member 48 is at the locking position, then the inclined face 66Q is brought into contact with the inclined face 48Q. If the unlocking projection 66 further moves to the rear side, then the locking member 48 is pushed to the outer side in the widthwise direction by the inclined face 66Q as depicted successively in FIG. 13C to FIG. 13D. Then, the locking member 48 moves to the unlocking position against the biasing force of the spring member 58. The unlocking projection 66 has such a degree of rigidity that, when the unlocking projection 66 pushes the locking member 48 in this manner, the unlocking projection 66 is not deformed inadvertently. It is to be noted that, even with an alternative structure wherein only one of the inclined faces 48Q and 66Q is formed, the unlocking projection 66 may push the locking member 48 to move it to the unlocking position.

As depicted in FIGS. 3, 8 and 9, a end wall 72 having a normal direction coincident with the depthwise direction is formed on the second rail member 22B through a connection plate 70. The attachment member 74 is provided on the connection plate 70 and the second end wall 72.

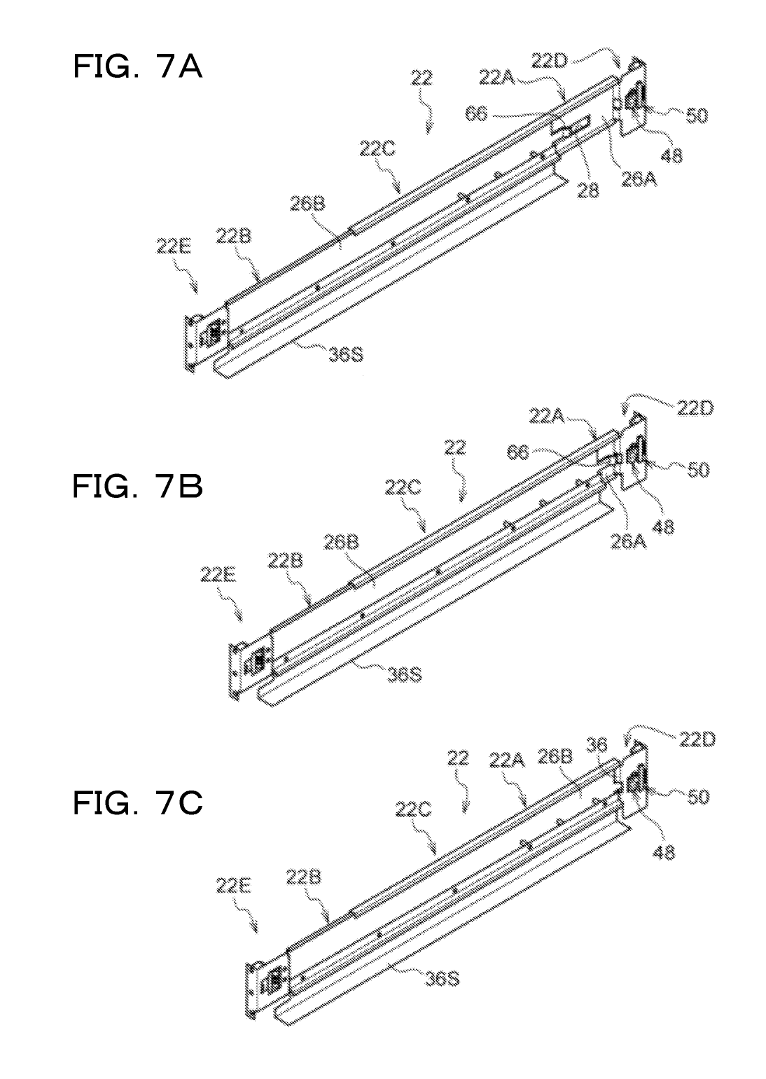

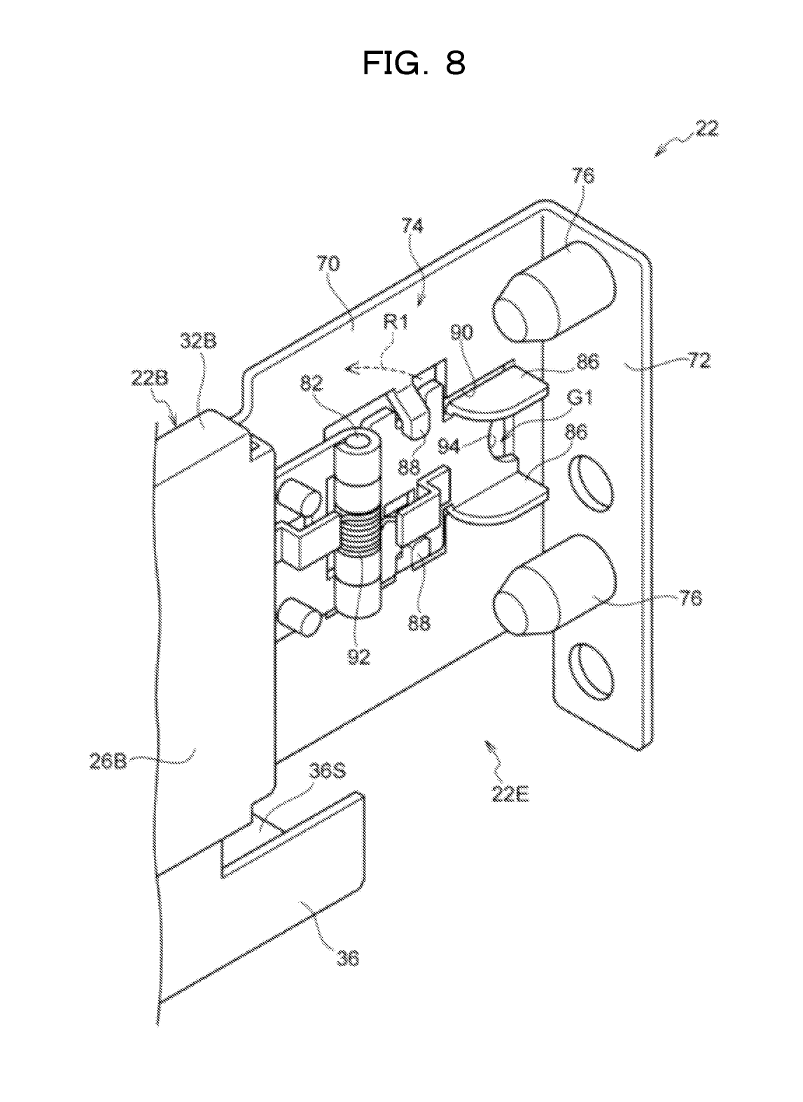

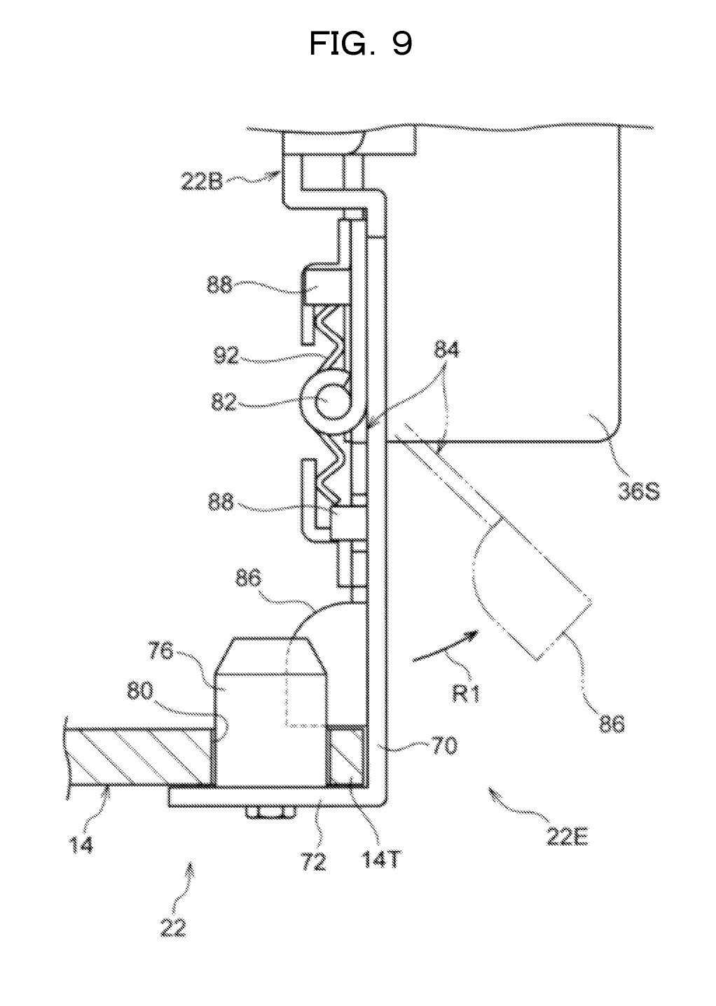

The attachment member 74 includes one or a plurality of engagement pins 76 (in the example depicted in FIG. 8, two engagement pins 76 spaced from each other in the vertical direction), and a holding member 78. The engagement pins 76 are provided so as to project rearwardly. The engagement pins 76 are inserted from the front side into and engaged with engagement holes 80 of the near side post 14 as depicted in FIG. 9.

The holding member 78 includes a pivot shaft 82 provided on the connection plate 70 of the second rail member 22B, and a rocking plate 84 rotatably mounted on the pivot shaft 82.

In the example depicted in FIG. 8, the pivot shaft 82 extends in the vertical direction. One or a plurality of locking plates 86 (in the example depicted in FIG. 8, two locking plates 86 spaced from each other in the vertical direction) are formed at a front side portion of the rocking plate 84 so as to be directed to the outer side in the widthwise direction.

The rocking plate 84 is rotatable around the pivot shaft 82 between a locking posture (indicated by a solid line in FIG. 9) in which the locking plates 86 project to the outer side in the widthwise direction and a non-locking posture (partly indicated by an alternate long and two short dashes line in FIG. 9) in which the locking plates 86 are retracted to the inner side in the widthwise direction.

Stopper pieces 88 are formed on the connection plate 70 at the front side with respect to the pivot shaft 82. When the connection plate 70 is in the locking posture, a rotation of the connection plate 70 in the opposite direction to an arrow mark R1 (toward the locking posture) is restricted through abutment of the connection plate 40 with the stopper pieces 88.

An escape hole 90 is formed on the connection plate 70 at the front side with respect to the pivot shaft 82. The pivotal motion of the connection plate 70 in the direction of the arrow mark R1 is permitted because the front side of the connection plate 70 enters the escape hole 90.

A rotationally biasing spring 92 is mounted on the pivot shaft 82. The rotationally biasing spring 92 biases the rocking plate 84 in the opposite direction to the direction of the arrow mark R1, for example, toward the locking posture.

A concave portion 94 is formed at the front end side of the rocking plate 84. A gap G1 is generated between the rocking plate 84 and the escape hole 90 by the concave portion 94. An operator may insert a tool or the like into the gap G1 and pivot the rocking plate 84 in the direction of the arrow mark R1 against the biasing force of the rotationally biasing spring 92.

The locking posture of the rocking plate 84 is a posture in which, in a state in which the engagement pins 76 engage with the engagement holes 80, the locking plates 86 are positioned on the rear side with respect to a tip end portion 14T of the near side post 14 as indicated by a solid line in FIG. 9. At this time, the tip end portion 14T of the near side post 14 is positioned between the end wall 72 and the locking plates 86.

In contrast, the unlocking posture of the rocking plate 84 is a posture in which the locking plates 86 are retracted from the tip end portion 14T of the near side post 14 as indicated by an alternate long and two short dashes line in FIG. 9. At this time, it is possible to move the second rail member 22B to the front side and remove the engagement pins 76 from the engagement holes 80.

As depicted in FIGS. 7A to 7C, it is possible to slidably move the first rail member 22A and the second rail member 22B relative to each other to elongate or contract the rack mount rail 22 as a whole. By the elongation or contraction of the rack mount rail 22, the position of the attachment member 74 (engagement pins 76 and holding member 78) with respect to the engagement pins 31 (distance of the attachment member 74 from the engagement pins 31) varies.

Subsequently, working and effects of the present embodiment and a method of attaching the rack mount rails 22 to the rack 10 and mounting an electronic device 20 on the rack mount rails 22 are described.

In order to attach the rack mount rails 22 to the rack 10, the front door 17 is opened first to open the opening 18. Then, each rack mount rail 22 is inserted into the rack 10 through the opening 18.

Then, the first fixing unit 22D of the rack mount rail 22 is fixed to the corresponding far side post 13 of the rack 10. For example, the engagement pins 31 are positioned on the rear side with respect to the far side post 13 as depicted in FIGS. 10A and 11A. At this time, the engagement pins 31 are positioned on the inner side in the widthwise direction with respect to the engagement holes 44. Further, the locking member 48 is at the locking position under the biasing force of the spring member 58.

Then, the first fixing unit 22D of the rack mount rail 22 is moved to the outer side in the widthwise direction, for example, toward the far side post 13 (in the direction of an arrow mark M1) as depicted in FIG. 11B. The tip end portion 13T of the far side post 13 and the flat face 48P of the locking member 48 are brought into contact with each other.

If the first fixing unit 22D side of the rack mount rail 22 is further moved to the outer side in the widthwise direction (direction of the arrow mark M1) as depicted in FIG. 11C, then the locking member 48 is pushed by the tip end portion 13T of the far side post 13. The locking member 48 moves relative to the first rail member 22A as indicated by an arrow mark M2 against the biasing force of the spring member 58 to move from the locking position to the unlocking position. Further, the positions of the engagement holes 44 and the engagement pins 31 coincide with each other as viewed in the depthwise direction (direction of the arrow mark L).

It is to be noted that, when the locking member 48 is to be moved from the locking position to the unlocking position, the second rail member 22B may be slidably moved to the rear side as depicted in FIGS. 13C and 13D. In this case, when the second rail member 22B is slidably moved, the inclined face 66Q of the unlocking projection 66 pushes the inclined face 48Q of the locking member 48, and consequently, the locking member 48 moves from the locking position to the unlocking position.

If, in this state, the rack mount rail 22 (or the first rail member 22A) is moved to the front side as indicated by an arrow mark M3 in FIG. 11D, then since the positions of the engagement holes 44 and the engagement pins 31 coincide with each other as viewed in the depthwise direction, the engagement pins 31 are inserted into the engagement holes 44. Until midway of the insertion, the tip end portion 13T of the far side post 13 and the flat face 48P of the locking member 48 continue to be in contact with each other.

If the rack mount rail 22 is further moved to the front side as depicted in FIG. 11E, then the flat face 48P of the locking member 48 is spaced away from the tip end portion 13T of the far side post 13. The locking member 48 is acted upon by the biasing force of the spring member 58 and moves to the locking position as indicated by an arrow mark M4. In this state, the tip end portion 13T of the far side post 13 is positioned between the locking member 48 and the bent wall 42.

If the rack mount rail 22 is further moved to the front side, then the bent wall 42 is brought into contact with the far side post 13 as depicted in FIG. 11F. In this state, even if the rack mount rail 22 is tried to move to the rear side, the locking member 48 is brought into abutment with the tip end portion 13T. Consequently, the movement of the rack mount rail 22 is restricted and it may be difficult to remove the engagement pins 31 from the engagement holes 44.

After the first fixing unit 22D is fixed to the far side post 13 in this manner, the second fixing unit 22E is fixed to a corresponding near side post 14. For example, the rack mount rail 22 is extended as indicated by an arrow mark M5 in FIG. 10B.

Then, the engagement pins 76 are positioned at the front side with respect to the near side post 14. In this state, the second fixing unit 22E side of the rack mount rail 22 is moved to the outer side in the widthwise direction. In a state in which the rocking plate 84 is in the unlocking state as a result of pushing of the locking plates 86 by the near side post 14, the second rail member 22B is slidably moved to the near side to insert the engagement pins 76 into the engagement holes 80. Since the tip end portion 14T of the near side post 14 is positioned between the locking plates 86 and the end wall 72 as depicted in FIG. 9, the sliding movement of the second rail member 22B is restricted, and the engagement pins 76 is not removable from the engagement holes 80.

The rack mount rail 22 is attached to the far side post 13 and the near side post 14 in this manner as depicted in FIG. 10C. Thus, an electronic device 20 may be supported by the supporting portions 36S of the one set of the left and right rack mount rails 22.

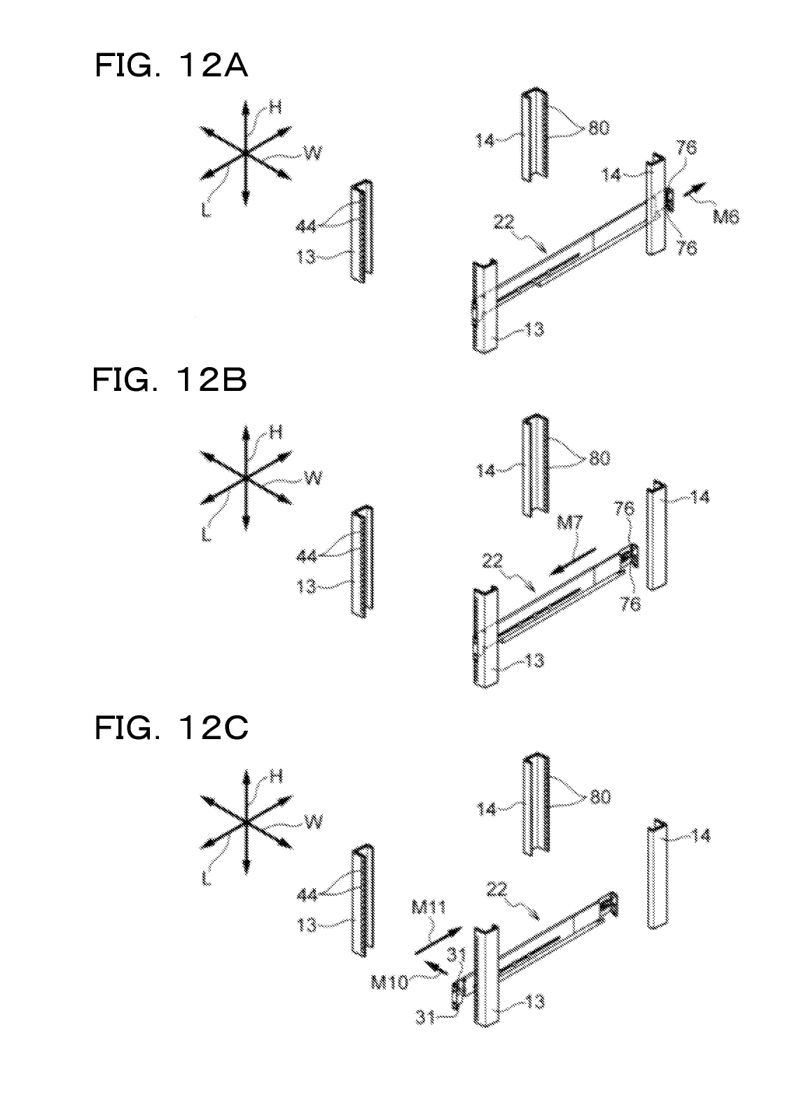

In order to remove the rack mount rail 22 from the rack 10, the operator would first insert its hand directly into or insert a tool or the like into the gap G1 and rock the rocking plate 84 to the unlocking position. Since the second rail member 22B is permitted to slidably move to the front side, the operator would slidably move the second rail member 22B to the front side as indicated by an arrow mark M6 in FIG. 12A and remove the engagement pins 31 from the engagement holes 44.

At this time, as depicted in FIG. 13A, the inclined face 66Q of the unlocking projection 66 is not in contact with the inclined face 48Q of the locking member 48.

If the second rail member 22B is slidably moved rearwardly as indicated by an arrow mark M7 in FIG. 13B, then the inclined face 66Q of the unlocking projection 66 is brought into contact with the inclined face 48Q of the locking member 48. Then, if the second rail member 22B is slidably moved rearwardly further, then the entire first rail member 22A is pushed to the rear side and the locking member 48 is brought into contact with the far side post 13.

If, in this state, the second rail member 22B is slidably moved rearwardly further, then the inclined face 66Q of the unlocking projection 66 pushes the inclined face 48Q of the locking member 48 as depicted in FIG. 13C. Consequently, the locking member 48 moves toward the unlocking position as indicated by an arrow mark M8 against the biasing force of the spring member 58.

Then, if the locking member 48 comes to the unlocking position as depicted in FIG. 13D, then a bent portion 66P of the unlocking projection 66 is brought into contact with the flat face 48P of the locking member 48. Consequently, the movement of the locking member 48 toward the locking position is restricted, and the locking member 48 is kept at the unlocking position.

In this state, the locking member 48 is not positioned at the front side of the tip end portion 13T of the far side post 13. If the second rail member 22B is further pushed rearwardly, then the second plate portion 28B is brought into abutment with the stopper wall 38 of the first rail member 22A. Accordingly, if the second rail member 22B is pushed rearwardly as indicated by an arrow mark M9 in FIG. 13E, then the first rail member 22A moves rearwardly. Then, the engagement pins 31 are removed from the engagement holes 44.

In the state in which the engagement pins 31 are removed from the engagement holes 44, the first fixing unit 22D side of the rack mount rail 22 is moved to the inner side in the widthwise direction as indicated by an mark M10 in FIG. 13F. As indicated by an arrow mark M11, the rack mount rail 22 may be pulled to the front side so as to come to the front side of the rack 10.

As recognized from the foregoing description, in the present embodiment, an operation for attaching and removing the first fixing unit 22D at the first end side of the rack mount rail 22 to and from the far side post 13 may be performed from the near side. As depicted in FIG. 1, the near side of the rack 10 is frequently closed with the electronic devices 20 or the closing plates 24, and it is difficult to insert a hand or a tool from the near side of the rack 10 to access to the first fixing unit 22D. For example, a case is assumed in which it is difficult to perform attachment or removal of the first fixing unit 22D to or from the far side post 13 of the rack 10S from the front side of the rack 10S depicted in FIG. 2. In this case, the operator would first perform, on the first passageway 19A, attachment or removal of the first fixing unit 22D of the rack mount rail 22 to or from the near side post 14 as indicated by an arrow mark M12. Then, the operator would go around to the second passageway 19B and confirm the position of the pertaining rack 10S and then perform attachment or removal of the second fixing portion of the rack mount rail 22 to or from the near side post 14 (or may perform such processes reversely).

In contrast, with the present embodiment, the operator may attach or remove the first fixing unit 22D of the rack mount rail 22 to or from the far side post 13 from the near side (first passageway 19A) of the rack 10S and may not need go around to the second passageway 19B. Further, the operator may not need open or close a rear door of the rack 10 either.

Besides, since the operation space for the attaching and removing operations for the rack mount rail 22 may not be required for the second passageway 19B, also it is possible to narrow the first passageway 19A and raise the arrangement density of the racks 10 in the installation room 19.

The rack mount rail 22 includes the first rail member 22A and the second rail member 22B. The rack mount rail 22 may further include a different slide member or members. If the rack mount rail 22 includes at least the first rail member 22A and the second rail member 22B, then the rack mount rail 22 may be expanded and contracted by sliding movement of the first rail member 22A and the second rail member 22B relative to each other by the simple structure.

The unlocking projection 66 is provided, in the embodiment described hereinabove, on the second rail member 22B. Accordingly, by a sliding operation of the second rail member 22B positioned at the second end side of the rack mount rail 22, the unlocking projection 66 may be moved to the far side to cancel the locking by the locking member 48.

Further, the “engaging member” and the “engaged portion” are not limited to the engagement pins 31 and the engagement holes 44, respectively, and a combination of an engaging pawl and an engaging recessed portion or the like may be applied instead. Since, in the first embodiment, the engaged portion is the engagement hole 44 and the engaging member is the engagement pin 31, the engagement pins 31 and the engagement holes 44 may be engaged with each other with certainty by inserting the engagement pins 31 into the engagement holes 44.

The engagement pins 31 enter the engagement holes 44 from the rear side of the far side post 13. For example, the engagement pins 31 may be brought into engagement with the engagement holes 44 by a movement of the rack mount rail 22 (first rail member 22A) to the front side.

For example, if the engagement pins 31 are provided on the bent wall 42 of the rack mount rail 22, then in the state in which the rack mount rail 22 is attached to the rack 10, the rack mount rail 22 does not protrude to the rear side farther than the far side post 13.

The locking member 48 moves between the locking position and the unlocking position. When the locking member 48 is at the locking position, the locking member 48 is opposed to the bent wall 42 such that part of the far side post 13 of the rack 10 is interposed between the locking member 48 and the bent wall 42 in the state in which the engagement pins 31 are received in the engagement holes 44. Consequently, the state in which the engagement pins 31 are received in the engagement holes 44 may be maintained. Since the locking member 48 at the unlocking position is not opposed to the bent wall 42, the engagement pins 31 may be inserted into and removed from the engagement holes 44.

Since the locking member 48 is biased to the locking position by the spring member 58, such a situation that the state in which the engagement pins 31 are inserted in the engagement holes 44 is cancelled inadvertently may be reduced.

The movement permitting hole 46 is formed in the first rail member 22A. The locking member 48 is permitted to project through the movement permitting hole 46 and assume the locking position.

The locking member 48 includes the holding member (skirt portion 64). Accordingly, the locking member 48 biased to the locking position by the spring member 58 may be held at the locking position.

For example, since the skirt portion 64 contacts with the periphery of the movement permitting hole 46 when the locking member 48 is at the locking position, the posture of the locking member 48 at the locking position may be maintained stably.

Even if the biasing force from the spring member 58 described hereinabove acts upon the locking member 48, the unlocking projection 66 may move the locking member 48 from the locking position to the unlocking position against the biasing force.

Besides, the direction of movement of the locking member 48 is a direction orthogonal to the sliding direction of the rack mount rail 22 (direction of the arrow mark M5 and direction of the arrow mark M7). For example, the direction of movement of the locking member 48 is a widthwise direction of the rack 10. Therefore, if the first fixing unit 22D side of the rack mount rail 22 is moved in the widthwise direction, then the locking member 48 may be abutted with the far side post 13 and moved to the unlocking position.

Further, the unlocking projection 66 can move the locking member 48 from the locking position to the unlocking position readily by a pushing-in operation of pushing the second rail member 22B into the first rail member 22A.

For example, by forming the inclined face 48Q of the locking member 48 and the inclined face 66Q of the unlocking projection 66, the pushing-in operation of the second rail member 22B may be converted into a movement of the locking member 48 from the locking position to the unlocking position.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. An electronic apparatus, comprising:
a rack including a far side post, a near side post, and an opening formed at a side of the near side post;
a pair of rail members configured to slidably move relative to each other, the pair of rail members including:
a first rail member attached to the far side post, and
a second rail member attached to the near side post;
an engaging member, provided at an end portion of the first rail member, configured to engage with an engaged portion formed on the far side post in a state in which the pair of rail members are inserted through the opening of the rack;
a locking member, provided on the first rail member, configured to block a movement of the engaging member in a disengaging direction;
an unlocking member, provided on the second rail member, configured to move the locking member to an unlocking position of the engaging member by a sliding operation of the second rail member; and
an electronic device mounted on the pair of rail members.

2. The electronic apparatus according to claim 1, wherein the engaged portion is an engagement hole formed on the far side post; and
the engaging member is an engagement pin configured to be inserted into the engagement hole.

3. The electronic apparatus according to claim 2, wherein the engagement pin is inserted into the engagement hole from a rear side of the far side post.

4. The electronic apparatus according to claim 2, wherein the engagement pin is provided at a first end side of the first rail member and projects from a bent wall that extends around to the rear side of the far side post.

5. The electronic apparatus according to claim 4, wherein the locking member moves between a locking position and the unlocking position, the locking member at the locking position being opposed to the bent wall across part of the far side post in a state in which the engagement pin is inserted in the engagement hole, and the locking member being not opposed to the bent wall at the unlocking position.

6. The electronic apparatus according to claim 5, further comprising:
a spring member configured to bias the locking member from the unlocking position to the locking position.

7. The electronic apparatus according to claim 6, further comprising:
a holding member configured to hold the locking member, upon which biasing force of the spring member acts, at the locking position.

8. The electronic apparatus according to claim 7, further comprising:
a hole, provided on the first rail member, configured to permit part of the locking member at the locking position to project from the first rail member.

9. The electronic apparatus according to claim 8, wherein the holding member is a contacting portion that is provided on the locking member and contacts with a wall portion around the hole at the locking position.

10. The electronic apparatus according to claim 6, wherein the unlocking member moves the locking member from the locking position to the unlocking position against biasing force of the spring member.

11. The electronic apparatus according to claim 5, wherein a direction of the movement of the locking member is orthogonal to a sliding direction of the pair of rail members.

12. The electronic apparatus according to claim 5, wherein the unlocking member moves the locking member to the unlocking position by pushing the second rail member into the first rail member.

13. The electronic apparatus according to claim 12, further comprising:
an inclined face, provided on at least one of the unlocking member and the locking member and being inclined with respect to the sliding direction, configured to move the locking member to the unlocking position when the pushing is performed in a state in which the unlocking member and the locking member contact with each other.

14. A rail structure, comprising:
a first rail member attached to a far side post of a rack;
a second rail member, attached to a near side post of the rack, configured to slidably move with respect to the first rail member;
an engaging member, provided at an end portion of the first rail member, configured to engage with an engaged portion formed on the far side post;
a locking member, provided on the first rail member, configured to block a movement of the engaging member in a disengaging direction; and
an unlocking member, provided on the second rail member, configured to move the locking member to an unlocking position of the engaging member by a sliding operation of the second rail member.

15. The rail structure according to claim 14, wherein the unlocking member moves the locking member to the unlocking position by pushing the second rail member into the first rail member.

16. The rail structure according to claim 15, further comprising:
an inclined face, provided on at least one of the unlocking member and the locking member and being inclined with respect to the sliding direction, configured to move the locking member to the unlocking position when the pushing is performed in a state in which the unlocking member and the locking member contact with each other.

17. A rack, comprising:
a far side post;
a near side post;
a pair of rail members configured to slidably move relative to each other, the pair of rail members including:
a first rail member attached to the far side post, and
a second rail member attached to the near side post;
an engaging member, provided at an end portion of the first rail member, configured to engage with an engaged portion formed on the far side post in a state in which the pair of rail members are inserted into an opening of the rack at the near side post side;
a locking member, provided on the first rail member, configured to block a movement of the engaging member in a disengaging direction; and
an unlocking member, provided on the second rail member, configured to move the locking member to an unlocking position of the engaging member by a sliding operation of the second rail member.

18. The rack according to claim 17, wherein the engaged portion is an engagement hole formed on the far side post; and
the engaging member is an engagement pin that is inserted into the engagement hole.
